(19) United States
(12) Patent Application Publication
(10) Pub. No.: US 2011/0100699 A1
(43) Pub. Date: May 5, 2011

(54) PRINTED CIRCUIT BOARD AND METHOD OF MANUFACTURING THE SAME

(76) Inventors: Masahi Hamazaki, Busan (KR); Dek Gin Yang, Chungcheongbuk-do (KR); Dong Hwan Lee, Gyeongsangnam-do (KR); Bong Soo Kim, Gyeongsangnam-do (KR); II Kyoon Jeon, Busan (KR); Kwang Yune Kim, Daegu (KR)

(21) Appl. No.: 12/716,212

(22) Filed: Mar. 2, 2010

(30) Foreign Application Priority Data
Nov. 4, 2009 (KR) 10-2009-0106175

(51) Int. Cl. H05K 1/11; H05K 3/42

(52) U.S. Cl. 174/266; 29/852

(57) ABSTRACT

Disclosed herein is a method of manufacturing a printed circuit board, including: forming a buildup layer on a base substrate including a circuit layer connected with a first via penetrating an insulation layer; forming a viahole penetrating the buildup layer and at least a part of the first via; and forming an interlayer connection member in the viahole. The method is advantageous in that a process of forming a multilayer connection structure can be simplified, and an error in the formation of a viahole can be minimized.

### CROSS REFERENCE TO RELATED APPLICATION

This application claims the benefit of Korean Patent Application No. 10-2009-0106175, filed Nov. 4, 2009, entitled “A printed circuit board and a fabricating method the same”, which is hereby incorporated by reference in its entirety into this application.

### BACKGROUND OF THE INVENTION

1. Technical Field

The present invention relates to a printed circuit board and a method of manufacturing the same.

2. Description of the Related Art

As electronic components become highly functionalized and light, thin, short and small, printed circuit boards mounting the electronic components are required to be highly densified. One of the technologies meeting such a requirement is the technology for making an electrical interlayer connection for circuit patterns and this has been actively researched. In particular, in order to reduce production costs, research into simplifying a process of forming a multi-layered via is being made.

FIGS. 1 to 4 are sectional views showing a conventional method of manufacturing a printed circuit board having a multilayered via. Hereinafter, the conventional method of manufacturing a printed circuit board having a multilayered via will be described with reference to FIGS. 1 to 4.

First, as shown in FIG. 1, a first buildup insulation layer 22 is formed on a base substrate 10 including a first insulation layer 12 and a first circuit layer 14 formed on the first insulation layer 12, and then a first viahole 24 is formed in the first buildup insulation layer 22.

Subsequently, as shown in FIG. 2, a first buildup circuit layer 26 including a first buildup via is formed on the first buildup insulation layer 22 using a plating process to form a first buildup layer 20 composed of the first buildup insulation layer 22 and the first buildup circuit layer 26.

Subsequently, as shown in FIG. 3, a second buildup insulation layer 32 is formed on the first buildup insulation layer 22, and then a second viahole 34 is formed in the second buildup insulation layer 32.

Finally, as shown in FIG. 4, a second buildup circuit layer 36 including a second buildup via is formed on the second buildup insulation layer 32 using a plating process to form a second buildup layer 30 composed of the second buildup insulation layer 32 and the second buildup circuit layer 36.

However, when a multilayered via structure is realized in this way, there is a problem in that the number of viahole forming processes and the number of plating processes are increased according to the increase in the number of buildup processes. That is, when buildup processes are performed two times, a process of forming the first viahole 24 and the second viahole 34 is required to be performed two times, and a plating process for forming the first buildup via 26 and the second buildup via 36 is required to be performed two times. Thus, there is caused a problem in that the yield of a process is greatly decreased.

### SUMMARY OF THE INVENTION

Accordingly, the present invention has been made to solve the above-mentioned problems, and the present invention provides a printed circuit board which can increase the yield of a process by simplifying a process of forming a multilayer connection structure, and a method of manufacturing the same.

An aspect of the present invention provides a printed circuit board, including: a base substrate including an insulating layer which is penetrated by a first via and a circuit layer connected with the first via penetrating the insulation layer; a buildup layer formed on the base substrate; and an interlayer connection member formed in a viahole penetrating the buildup layer and at least a part of the first via.

Here, the viahole may be formed such that the lower end thereof is positioned within the range of the height of the first via.

Further, the interlayer connection member may be formed of a plating layer or conductive paste.

Another aspect of the present invention provides a method of manufacturing a printed circuit board, including: forming a buildup layer on a base substrate including a circuit layer connected with a first via penetrating an insulation layer; forming a viahole penetrating the buildup layer and at least a part of the first via; and forming an interlayer connection member in the viahole.

In the method, in the forming of the viahole, the viahole may be formed using a drilling machine.

Further, in the forming of the viahole, the viahole may be formed such that the lower end thereof is positioned within the range of the height of the first via.

Further, in the forming of the interlayer connection member, the interlayer connection member may be formed by performing a plating process in the viahole or charging conductive paste in the viahole.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 4 are sectional views showing a conventional method of manufacturing a printed circuit board having a multilayered via;

FIG. 5 is a sectional view showing a printed circuit board according to an embodiment of the present invention;

FIGS. 6 to 8 are sectional views showing a method of manufacturing a printed circuit board according to an embodiment of the present invention;

FIGS. 9 and 10 are views for explaining a drilling depth control system according to an embodiment of the present invention; and

FIGS. 11 and 12 (12A to 12C) are views for explaining a drilling depth control system according to another embodiment of the present invention.

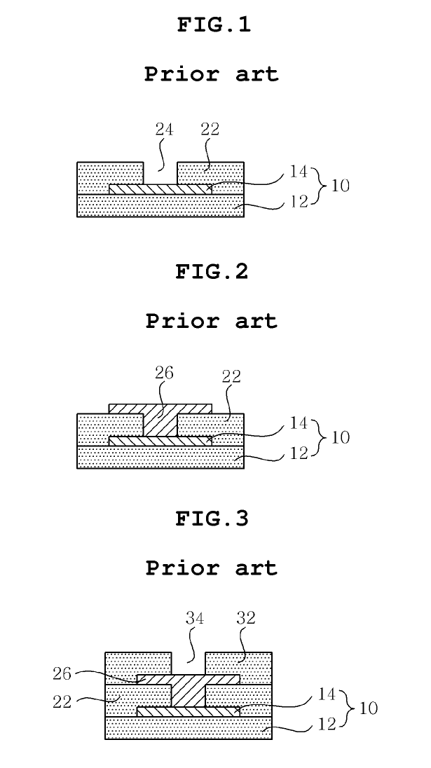

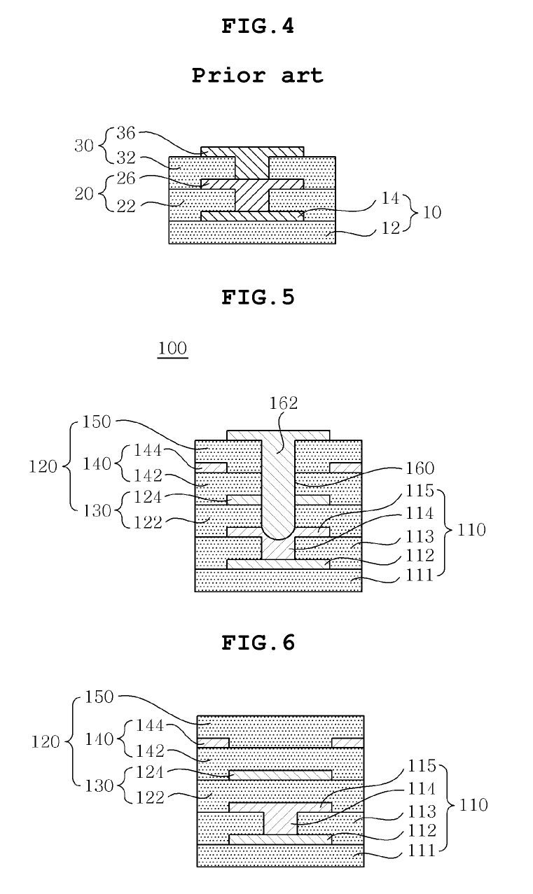

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

FIG. 5 is a sectional view showing a printed circuit board according to an embodiment of the present invention. Hereinafter, the printed circuit board 100 according to this embodiment will be described in detail with reference to FIG. 5.

As shown in FIG. 5, the printed circuit board 100 according to this embodiment includes a base substrate 110 including a circuit layer 115 connected with a first via 114, a buildup layer 120 formed on the base substrate 110, and an interlayer connection member 162 formed in a viahole 160 penetrating the buildup layer 120 and at least a part of the first via 114. That is, the printed circuit board 100 has a structure in which the viahole 160 is formed to penetrate the buildup layer 120 having a multilayered structure and at least a part of the first via 114 and the interlayer connection member 162 is formed in the viahole 160.

Here, the base substrate 110 has a structure in which an insulation layer 113 is formed on a base insulation layer 111 including a base circuit layer 112 formed thereon and a circuit layer 115, which is connected with the base circuit layer 112 through the first via 114, is formed on the insulation layer 113.

Here, the viahole 160 is formed not only through the entire buildup layer 120 but also through at least a part of the first via 114, that is, the viahole 160 is formed such that the lower end thereof is positioned within the range of the height of the first via 114, and the interlayer connection member 162 is formed in the viahole 160.

The interlayer connection member 162 serves to electrically connect circuit layers 124 and 144 of the buildup layer 120 with the via 114 of the base substrate 110, and may be formed of a plating layer or conductive paste.

FIGS. 6 to 8 are sectional views showing a method of manufacturing a printed circuit board according to an embodiment of the present invention. Hereinafter, the method of manufacturing a printed circuit board according to this embodiment will be described with reference to FIGS. 6 to 8.

First, as shown in FIG. 6, a buildup layer 120 is formed on a base substrate 110 including an insulation layer 113 on which a circuit layer (land) 115 connected with a first via 114 is formed.

Here, the base substrate 110 has a structure in which a circuit layer 115 connected with a first via 114 is formed on an insulation layer 113. For example, FIG. 6 shows a structure in which an insulation layer 113 is formed on a base insulation layer 111 including a base circuit layer 112 formed thereon and a circuit layer 115 connected with the base circuit layer 112 through a first via 114 is formed on the insulation layer 113.

Further, the buildup layer 120 is formed by a buildup method in which buildup insulation layers 122, 142 and 150 are sequentially placed on the base substrate 110 and then buildup circuit layers 124 and 144 are formed on the buildup insulation layers 122 and 142. For example, FIG. 6 shows a multilayered buildup layer 120 including: a first buildup layer 130 composed of a first buildup insulation layer 122 and a first buildup circuit layer 124 formed thereon; a second buildup layer 140 composed of a second buildup insulation layer 142 and a second buildup circuit layer 144 formed thereon; and a third buildup insulation layer 150.

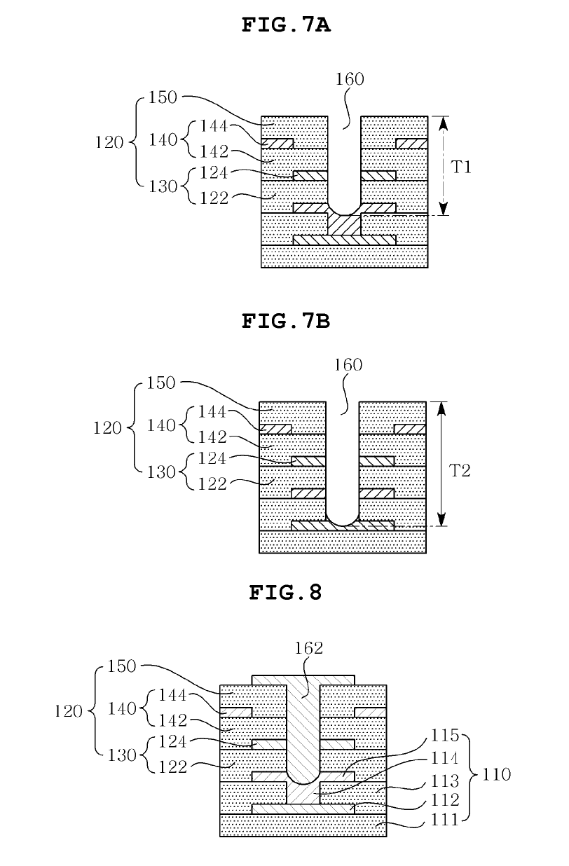

Subsequently, as shown in FIGS. 7A and 7B, a viahole 160 penetrating the buildup layer 120 and at least a part of the first via is formed using a drilling machine. In this case, the viahole 160 is formed such that an interlayer connection member 162, which is formed therein later, can perform an interlayer connection function. Therefore, in the present invention, the viahole 160 can be formed such that the lower end thereof is positioned within the range of the height of the first via 114. Meanwhile, although not shown, even when the viahole 160 is formed to the circuit layer 115 connected with the first via, the interlayer connection member 162 can perform an interlayer connection function because it can be connected with the circuit layer 115. Therefore, this configuration is also included in the scope of the present invention.

That is, in conventional technologies, vias for interlayer connection are formed whenever buildup layers are formed, but, in the present invention, a viahole 160 for multilayer connection is formed after a multilayered buildup layer is formed.

In this case, when the viahole 160 penetrating the multilayered buildup layer 120 is formed, there is a problem in that the viahole 160 is excessively or insufficiently formed due to the error unavoidably occurring when controlling the drilling depth of a drilling machine. However, in the present invention, since the viahole 160 is formed such that the lower end thereof is positioned within the range of the height of the first via 114 formed in the base substrate 110 (or within the range of the height of the circuit layer 115 plus the first via 114), the tolerance of the error is increased, so that the above-problem can be overcome.

For example, FIG. 7A shows a viahole 160 having a depth of T1, and FIG. 7B shows a viahole 160 having a depth of T2 (T2>T1). Referring to FIGS. 7A and 7B, the viahole 160 may be variously formed between the upper limit and the lower limit of the range of the first via 114 plus the circuit layer 115, and thus the error occurring when controlling the drilling depth of a drilling machine can be compensated for.

Meanwhile, the formation of the viahole 160 is controlled using a drilling depth control system, and the drilling depth control system will be described later.

Finally, as shown in FIG. 8, an interlayer connection member 162 is formed in the viahole 160. In this case, the interlayer connection member 162 serves a multilayered via because it is connected with the first via 114. Meanwhile, it is shown in FIG. 8 that the interlayer connecting member 162 is formed by plating, but the interlayer connection member 162 may be formed by charging conductive paste in the viahole 160.

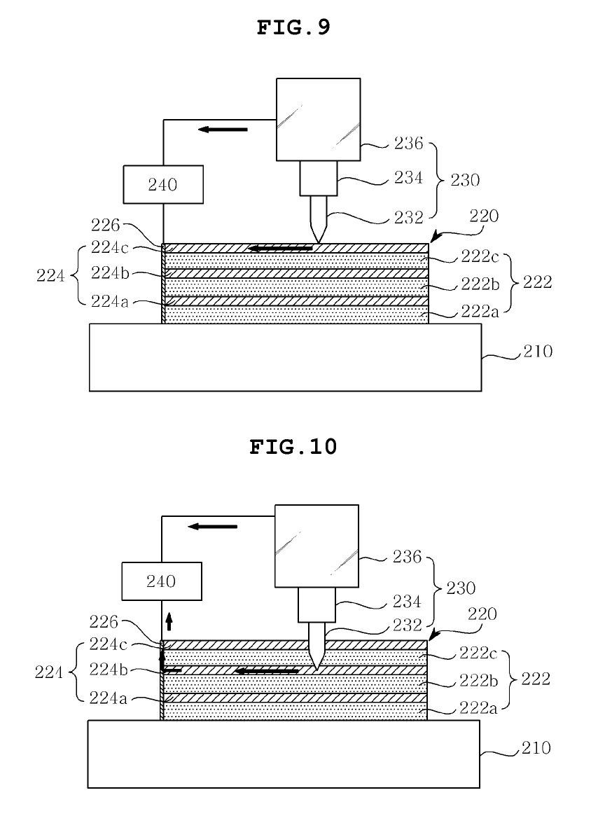

FIGS. 9 and 10 are views explaining a drilling depth control system according to an embodiment of the present invention. Hereinafter, the drilling depth control system according to this embodiment will be described with reference to FIGS. 9 and 10.

First, as shown in FIG. 9, a workpiece substrate 220 having an auxiliary via 226 electrically connected with circuit layers 224a, 224b and 224c is fixed on a workbench 210, and then an ammeter 240 is connected with the auxiliary via 226 and a drilling machine 230. Subsequently, the drilling machine 230 is gradually lifted down, and then a primary contact point between the third circuit layer 224c disposed at the uppermost part of the workpiece substrate 220 and a drill bit of the drilling machine 230 is detected using the ammeter, thus determining a reference position. That is, the primary contact point becomes a reference position for forming a viahole.

Here, the workpiece substrate 220, which is a substrate for forming a viahole, has a structure in which the auxiliary via 226 electrically connected with the circuit layers 224a, 224b and 224c is formed on a lateral side of the workpiece substrate 220. For example, it is shown in FIG. 9 that the workpiece substrate has a three-layered structure in which a first circuit layer 224a is formed on a first insulation layer 222a, a second circuit layer 224b is formed on a second insulation layer 222b, and a third circuit layer 224c is formed on a third insulation layer 222c, and in which an auxiliary via 226 electrically connected with the first, second and third circuit layers 224a, 224b and 224c is formed on a lateral side of the workpiece substrate 220.

Further, the drilling machine 230 is not particularly limited as long as it is commonly known in the related art, and may include a drill bit 232 which makes a hole in the workpiece substrate 220, a head 236 which is moved up and down by a drive motor mounted therein, and a spindle 234 which is disposed beneath the head 236 and engaged with the drill bit 232.

Subsequently, as shown in FIG. 10, a viahole is formed in the workpiece substrate 220 using the drill bit 232. In this case, the ammeter 240 detects whether or not the drill bit 232 comes into contact with the second circuit layer 224b, thus controlling the depth of a viahole to be formed. Here, since the second circuit layer 224b is connected with the ammeter 240 through the auxiliary via 226, the contact between the drill bit 232 and the second circuit layer 224b can be detected using the ammeter 240.

When such a drilling depth control system is applied to the present invention, in the present invention, the depth of a viahole to be formed is determined by detecting whether or not the drill bit 232 comes into contact with the first via 114 using the ammeter 240. In this case, even when an error in the depth of a viahole occurs by the detection error of the ammeter 240, a tolerance corresponding to the height of the first via 114 is given, thus overcoming the occurrence of the error.

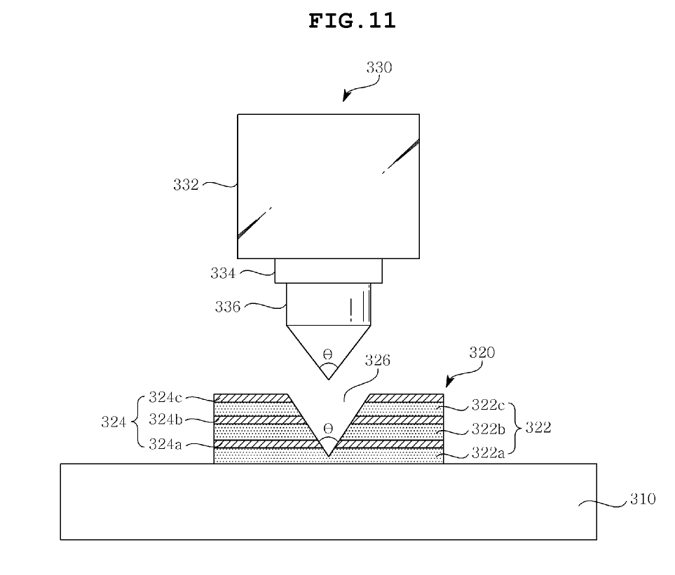

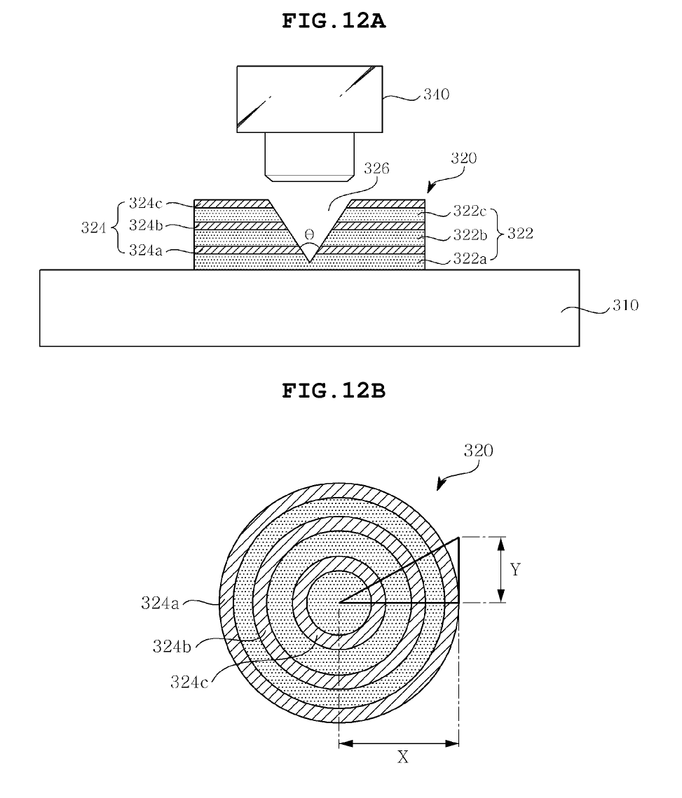

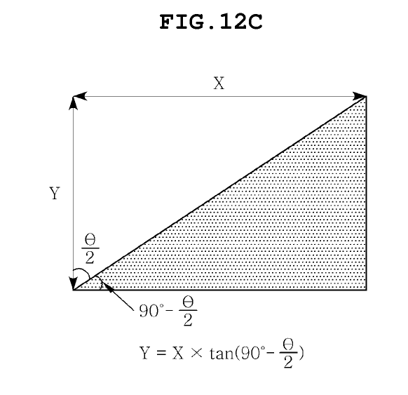

FIGS. 11 and 12 (12A to 12C) are views explaining a drilling depth control system according to another embodiment of the present invention. Hereinafter, the drilling depth control system according to this embodiment will be described with reference to FIGS. 11 and 12.

First, as shown in FIG. 11, a workpiece substrate 320 is fixed on a workbench 310, and then a viahole 326 is formed in the workpiece substrate 320 using a drilling machine 330 by estimating a theoretical interlayer distance.

The drilling machine 330 includes a drill bit 332 which makes a hole in the workpiece substrate 320, a head 336 which is moved up and down by a drive motor mounted therein, and a spindle 334 which is disposed beneath the head 336 and engaged with the drill bit 332.

In this case, the viahole 326 is formed such that it has the same inclined angle (θ) as that of the drill bit 332.

Subsequently, as shown in FIG. 12 (12A to 12C), an image of the viahole 326 is taken using a camera 340, and then the depth of the viahole 326 is measured using the image taken by the camera 340.

FIG. 12B shows the image of the viahole 326 taken using the camera 340. From FIG. 12B, it can be seen that insulation layers 322a, 322b and 322c can be distinguished from circuit layers 324a, 324b and 324c using the image difference attributable to the difference of texture therebetween. In this case, the horizontal distance (X) of the viahole 326 can be calculated by the image taken by the camera 340.

Meanwhile, FIG. 12C shows a graph for calculating the depth (Y) of the viahole 326 using the horizontal distance and inclined angle (θ) thereof. That is, the depth (Y) of the viahole 326 is calculated by the Equation Y=X*tan(90°−θ).

When such a drilling depth control system is applied to the present invention, the depth of the viahole 326 is determined by the image of the viahole 326 taken by the camera 340. In this case, even when an error in the depth of the viahole 326 occurs, a tolerance corresponding to the height of the first via 114 is given, thus overcoming the occurrence of the error.

As described above, according to the present invention, a buildup layer is formed on a base substrate having a first via, and then a viahole penetrating at least a part of the first via is formed in the base substrate, and then an interlayer connection member is formed in the viahole to form a multilayer connection structure, so that a manufacturing process is simplified compared to conventional methods, thereby increasing a process yield.

Further, according to the present invention, a viahole can be formed in the range of the height of a first via, thus overcoming an error in the depth of the viahole, the error occurring when controlling the drilling depth of a drilling machine.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. A printed circuit board, comprising:
a base substrate including an insulating layer which is penetrated by a first via and a circuit layer connected with the first via penetrating the insulation layer;
a buildup layer formed on the base substrate; and
an interlayer connection member formed in a viahole penetrating the buildup layer and at least a part of the first via.

2. The printed circuit board according to claim 1, wherein the viahole is formed such that a lower end thereof is positioned within the range of a height of the first via.

3. The printed circuit board according to claim 1, wherein the interlayer connection member is formed of a plating layer or conductive paste.

4. A method of manufacturing a printed circuit board, comprising:
forming a buildup layer on a base substrate including a circuit layer connected with a first via penetrating an insulation layer;
forming a viahole penetrating the buildup layer and at least a part of the first via; and
forming an interlayer connection member in the viahole.

5. The method of manufacturing a printed circuit board according to claim 4, wherein, in the forming of the viahole, the viahole is formed using a drilling machine.

6. The method of manufacturing a printed circuit board according to claim 4, wherein, in the forming of the viahole, the viahole is formed such that a lower end thereof is positioned within the range of a height of the first via.

7. The method of manufacturing a printed circuit board according to claim 4, wherein, in the forming of the interlayer connection member, the interlayer connection member is formed by performing a plating process in the viahole or charging conductive paste in the viahole.
